(19) United States
(12) Patent Application Publication
(10) Pub. No.: US 2012/0256255 A1
(43) Pub. Date: Oct. 11, 2012

(54) RECESSED TRENCH GATE STRUCTURE AND METHOD OF FABRICATING THE SAME

(76) Inventors: Tieh-Chiang Wu, Taoyuan County (TW); Yi-Nan Chen, Taipei City (TW); Hsien-Wen Liu, Taoyuan County (TW)

(21) Appl. No.: 13/081,498

(22) Filed: Apr. 7, 2011

(51) Int. Cl. H01L 29/78; H01L 21/336

(52) U.S. Cl. 257/330; 438/270; 257/E21.41; 257/E29.262

(57) ABSTRACT

A recessed trench gate structure is provided. The recessed trench gate structure includes a substrate with a recessed trench, a gate dielectric layer disposed around an inner surface of the recessed trench, a lower gate conductor disposed at a lower portion of the recessed trench and on the gate dielectric layer. Specially, the lower gate conductor has a convex top surface. A spacer is disposed along an inner side wall of a upper portion of the recessed trench and a upper gate conductor is disposed on the lower gate conductor. The convex top surface can prevent the electric field from distributing not uniformly, so that the GIDL can be prevented.

### BACKGROUND OF THE INVENTION

1. Field of the Invention

The present invention relates to a recessed trench gate structure and method of fabricating the same, and more particularly, the present invention relates to a structure which can reduce gate-induced drain leakage (GIDL).

2. Description of the Prior Art

In the fabrication of a semiconductor device, a planar gate forming method is used to form a gate on a planar active region. However, the channel length decreases due to a reduction in the pattern size and the electric field increases due to an increase in the ion implant doping concentration of the substrate. However, the reduction of the channel length and the increase of the doping concentration cause the short channel effect.

To solve the short channel effect, a transistor structure having a recessed gate has been proposed in the art in place of a conventional transistor structure having a planar gate. In the transistor structure having a recessed gate, the gate formed in a recessed trench in a substrate. When compared to the conventional transistor having a planar gate, a channel length of the transistor having a recessed gate can be further increased in the same area, and thus, the short channel effect can be efficiently suppressed.

However, because the fabricating steps of the recessed gate, a high electric field will accumulate at a pointed tip of the gate. Therefore, the high electric field causes GIDL, which deteriorates the data retention time.

### SUMMARY OF THE INVENTION

In light of above, the present invention provides a recessed trench gate structure and a method of fabricating the same.

According to a first preferred embodiment of the present invention, a method of fabricating a recessed trench gate structure includes the steps as follows. First, a substrate with a recessed trench therein is provided. Then, a gate dielectric layer is formed on an inner surface of the recessed trench. Later, a lower gate conductor is formed at the lower portion of the recessed trench, wherein the lower gate conductor has a convex top surface. After that, a spacer is formed along an inner side wall of the upper portion of the recessed trench. Finally, the upper portion of the recessed trench is filled with a upper gate conductor.

According to a second preferred embodiment of the present invention, a recessed trench gate structure, includes: a substrate with a recessed trench therein, a gate dielectric layer disposed around an inner surface of the recessed trench, a lower gate conductor disposed at a lower portion of the recessed trench and on the gate dielectric layer, wherein the lower gate conductor has a convex top surface, a spacer disposed along an inner side wall of a upper portion of the recessed trench and a upper gate conductor disposed on the lower gate conductor.

One of the features in the present invention is that the lower gate conductor is formed by an epitaxial silicon growth process therefore, the lower gate conductor has a convex top surface. The convex top surface can prevent the unevenly distribution of the electric field on the lower gate conductor. As a result, the GIDL can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 depict fabricating steps of a recessed trench gate structure of the present invention according to a first embodiment of the present invention.

FIG. 6 to FIG. 7 depict a varied type of the first embodiment schematically.

### DETAILED DESCRIPTION

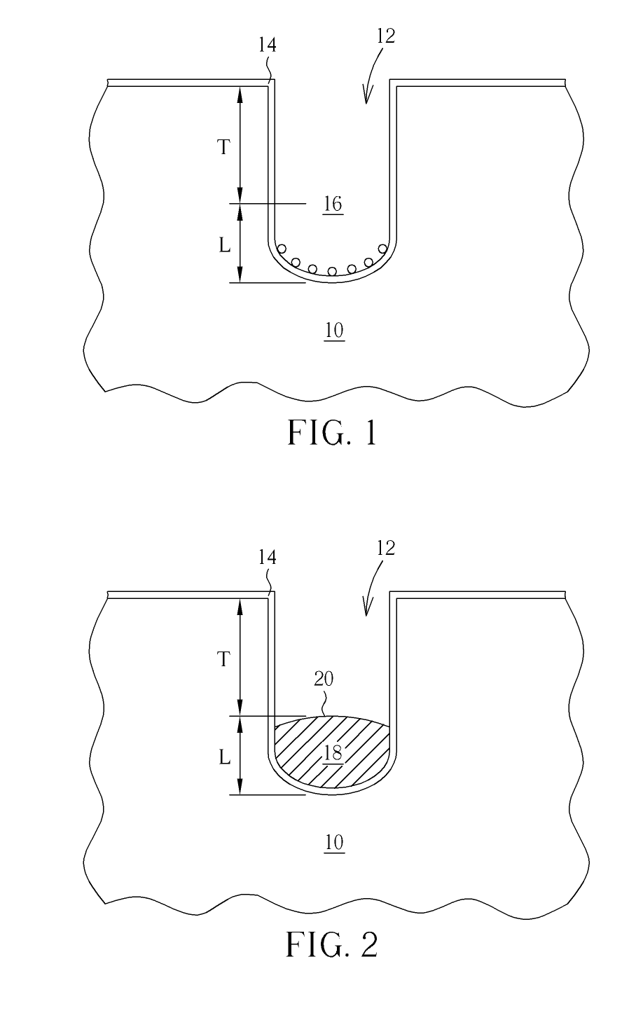

FIG. 1 to FIG. 5 depict fabricating steps of a recessed trench gate structure of the present invention according to the first embodiment of the present invention. As shown in FIG. 1, first, a semiconductor substrate 10 is provided. Then, a recessed trench 12 is formed in the semiconductor substrate 10. The recess trench 12 can be divided into a upper portion T and a lower portion L. After that, a gate dielectric layer 14 such as a silicon oxide layer can be formed on the inner surface of the recessed trench 12 by an oxidation process or a deposition process. Later, a silicon seed layer 16 is formed on the gate dielectric layer 14 at the bottom of the recessed trench 12.

As shown in FIG. 2, a lower gate conductor 18 is formed at the lower portion L of the recessed trench 12. The lower gate conductor 18 can be an epitaxial silicon layer such as an epitaxial polysilicon layer formed by an epitaxial silicon growth process. It is noted that according to the silicon crystal structure, the grown lower gate conductor 18 will have a convex top surface 20.

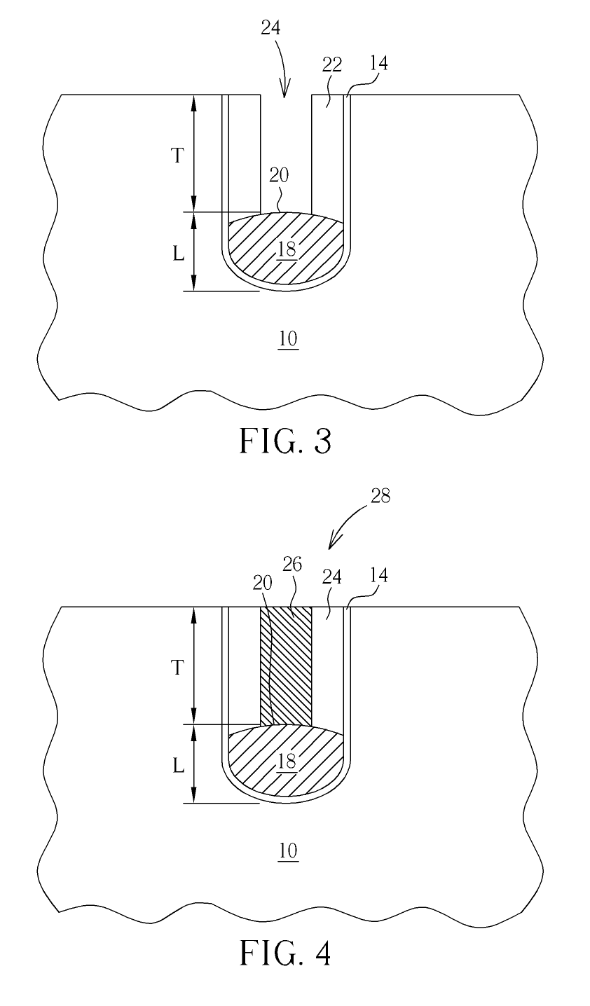

As show in FIG. 3, a spacer material layer (not shown) is formed on the surface of the semiconductor substrate 10, on the inner side wall of the upper portion T of the recessed trench 12 and on the convex top surface 20. Then, a spacer 22 is formed along the inner side wall of the upper portion T of the recessed trench 12 by etching the spacer material layer. More specifically, the spacer 22 is formed directly on the convex top surface 20 of the lower gate conductor 18. At this point, there is a trench 24 between the spacer 22 at the upper portion T of the recessed trench 12. As shown in FIG. 4, subsequently, a upper conductor gate 26 is formed to fill up the upper portion T of the recessed trench 12 between the spacer 22. The upper conductor gate 26 may be silicon or other conductive materials such as metals. At this point, the recessed trench gate structure 28 of the present invention is completed.

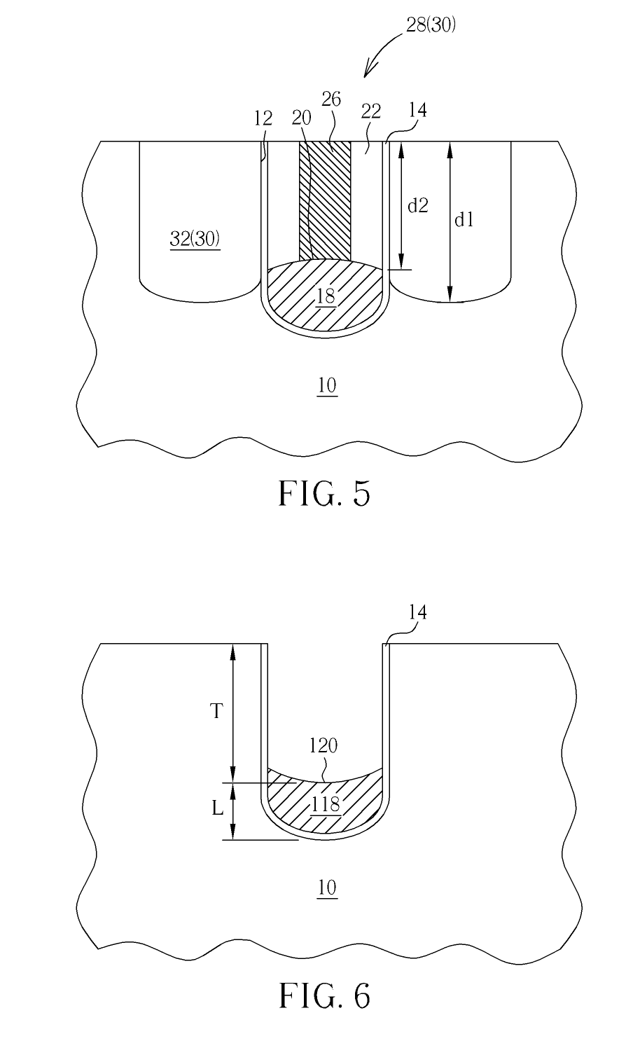

As shown in FIG. 5, after the recessed trench gate structure 28 is finished, a recessed trench gate transistor 30 can be formed by forming a source/drain doping region 32 in the semiconductor substrate 10 at each side of the recessed trench gate structure 28. A junction depth dl of the source/drain doping region 32 is deeper than a bottom depth d2 of the spacer 22.

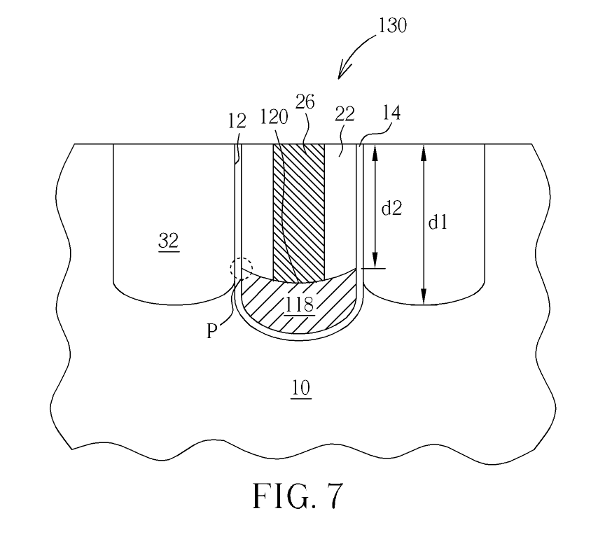

FIG. 6 to FIG. 7 depict a varied type of the first embodiment schematically, wherein elements with the same function will be designated with the same number. According to a varied type of the first embodiment of the present invention, the step of the epitaxial silicon growth process for forming the lower gate conductor 18 can be replaced by a deposition process. As shown in FIG. 6, first, a silicon layer (not shown) is formed to fill up the recessed trench 12 and on the top surface of the semiconductor substrate 10. Then, an etching process is performed to remove the silicon layer at the upper portion T of the recessed trench 12 and on the top semiconductor substrate 10. The remaining silicon layer in the recessed trench 12 becomes the lower gate conductor 118. It is noted that the lower gate conductor 118 undergone an etch back process therefore has concave top surface 120. Later, the spacer 22, the top gate conductor 26 and the source/drain doping region 32 are formed subsequently. A varied type recessed trench gate transistor 130 as shown in FIG. 7 is completed.

According to a second embodiment of the present invention, a recessed trench gate structure is provided in the present invention. As shown in FIG. 5, the recessed trench gate structure 28 includes: a semiconductor substrate 10 with a recessed trench 12. A gate dielectric layer 14 such as silicon oxide is disposed around an inner surface of the recessed trench 12. A lower gate conductor 18 having a convex top surface 20 is disposed at a lower portion L of the recessed trench 12 and on the gate dielectric layer 14. For the sake of brevity, please refer to FIG. 4 for the positions of the lower portion L and upper portion T of the recessed trench 12. The lower gate conductor 18 is preferably an epitaxial polysilicon layer but not limited to it. The lower gate conductor 18 can be any other conductive materials such as metals. Because the crystal structure of the polysilicon layer, the top surface 20 of the lower gate conductor 18 can be convex. In other words, the top surface of the lower gate conductor 18 bends toward the bottom of the recessed trench 12. The recessed trench gate structure of 28 the present invention further comprises a spacer 22 disposed along an inner side wall of a upper portion T of the recessed trench 12, and the spacer 22 is disposed directly on the lower gate conductor 18. A upper gate conductor 26 is disposed on the lower gate conductor 18 and between the spacer 22. The upper gate conductor 26 can be silicon layer such as polysilicon, mono-silicon or amorphous silicon, but not limited to them. The upper gate conductor 26 may also be other conductive materials such as metals.

The recessed trench gate structure 28 can become a recessed trench gate transistor 30 with a source/drain doping region 32 disposed in the semiconductor substrate 10 at each side of the recessed trench gate structure 28. The junction depth dl of the source/drain doping region 32 is deeper than a bottom depth d2 of the spacer.

Comparing the recessed trench gate transistor in FIG. 5 and FIG. 7, the lower gate conductor 118 in FIG. 7 has a pointed tip P sandwiched between the gate dielectric layer 14 and the spacer 22. On the contrary, the lower gate conductor 18 of the recessed trench gate transistor 30 in FIG. 5 does not have any pointed tip. Because the electric field is strong at the point tips, the pointed tip P in FIG. 7 may induce GIDL. However, the lower gate conductor in FIG. 5 has a smooth convex top surface, therefore, the electric field distributes evenly. Therefore, the GIDL can be prevented, and the data retention time can be increased.

Those skilled in the art will readily observe that numerous modifications and alterations of the device and method may be made while retaining the teachings of the invention.

What is claimed is:

1. A method of fabricating a recessed trench gate structure, comprising:
providing a substrate with a recessed trench therein;
forming a gate dielectric layer on an inner surface of the recessed trench;
forming a lower gate conductor at a lower portion of the recessed trench, wherein the lower gate conductor has a convex top surface;
forming a spacer along an inner side wall of a upper portion of the recessed trench; and
filling the upper portion of the recessed trench with a upper gate conductor.

2. The method of fabricating a recessed trench gate structure according to claim 1, wherein the lower gate conductor comprises an epitaxial silicon layer.

3. The method of fabricating a recessed trench gate structure according to claim 2, wherein the step of forming the lower gate conductor comprises:
forming a silicon seed layer on the gate dielectric layer;
performing an epitaxial silicon growth process to form the lower gate conductor.

4. The method of fabricating a recessed trench gate structure according to claim 1, wherein the lower gate conductor is formed before the spacer.

5. The method of fabricating a recessed trench gate structure according to claim 1, wherein the spacer is formed directly on the convex top surface of the lower gate conductor.

6. The method of fabricating a recessed trench gate structure according to claim 1, further comprising:
after filling the upper portion of the recessed trench with the upper gate conductor, forming a source/drain doping region in the substrate at each side of the recessed trench gate structure, wherein a junction depth of the source/drain doping region is deeper than a bottom depth of the spacer.

7. A recessed trench gate structure, comprising:
a substrate with a recessed trench therein;
a gate dielectric layer disposed around an inner surface of the recessed trench;
a lower gate conductor disposed at a lower portion of the recessed trench and on the gate dielectric layer, wherein the lower gate conductor has a convex top surface;
a spacer disposed along an inner side wall of a upper portion of the recessed trench; and
a upper gate conductor disposed on the lower gate conductor.

8. The recessed trench gate structure according to claim 7, wherein the lower gate conductor comprises an epitaxial silicon layer.

9. The recessed trench gate structure according to claim 7, further comprising:
a source/drain doping region disposed in the substrate at each side of the recessed trench gate structure, wherein a junction depth of the source/drain doping region is deeper than a bottom depth of the spacer.

10. The recessed trench gate structure according to claim 7, wherein the spacer is disposed directly on the convex top surface of the lower gate conductor.
